(19) United States
(12) Patent Application Publication
(10) Pub. No.: US 2023/0398698 A1
(43) Pub. Date: Dec. 14, 2023

(54) ADSORPTION NOZZLE, COMPONENT TRANSFER APPARATUS, AND ATTITUDE CONTROL METHOD OF ADSORPTION NOZZLE

(71) Applicant: YAMAHA HATSUDOKI KABUSHIKI KAISHA, Iwata-shi, Shizuoka (JP)

(72) Inventor: Tomohiro HIRANO, Iwata-shi (JP)

(73) Assignee: YAMAHA HATSUDOKI KABUSHIKI KAISHA, Iwata-shi, Shizuoka (JP)

(21) Appl. No.: 18/253,376

(22) PCT Filed: Dec. 10, 2020
(86) PCT No.: PCT/JP2020/046024

§ 371 Date: May 17, 2023

(51) Int. Cl. B25J 15/00; B25J 9/00; B25J 15/06

(52) U.S. Cl. CPC B25J 15/0019; B25J 9/0096; B25J 15/0616

(57) ABSTRACT

The invention includes: an axial nozzle member having a tip portion configured to adsorb a component; a holder member configured to slidably hold the nozzle member in a nozzle projection direction parallel to an axis line of the nozzle member; an urging member configured to generate an urging force to slide the nozzle member in the nozzle projection direction and cause the tip portion of the nozzle member to be projected from the holder member; and a locking part configured to locking the nozzle member projected from the holder member by the urging force, to thereby position the tip portion of the nozzle member at a projection limit position. The locking part locks the nozzle member at a first locking position and a second locking position which are asymmetric with respect to the axis line. Thus, a rotational moment is given to the nozzle member projected in the nozzle projection direction by the urging force in a rotation direction which is uniquely determined by a relative relationship between the first locking position and the second locking position with respect to the axis line.

### CROSS-REFERENCE TO RELATED APPLICATION

This application is a National Stage of International Patent Application No. PCT/JP2020/046024, filed Dec. 10, 2020, the entire contents of which is incorporated herein by reference.

### BACKGROUND

### Technical Field

The present disclosure relates to an attitude control technology of an adsorption nozzle which adsorbs a component by a tip portion of a nozzle member.

### Background Art

In a component mounting apparatus, as disclosed in JP2006-114534, for example, provided is a component transfer apparatus which transfers a component by using an adsorption nozzle having a buffing function. In the adsorption nozzle, an axial nozzle member having a tip portion which adsorbs a component is held freely movable in and out in an axial direction with respect to a holder member. Further, an urging member such as a spring or the like is provided inside the holder member and makes an urge to cause the tip portion of the nozzle member to be projected from the holder member in the axial direction, to thereby give the buffing function to the adsorption nozzle. For this reason, a variation in positioning in the axial direction, a variation of an outer shape of a component itself, or variations in the axial direction, which are caused by various factors such as a warp of a printed circuit board, a lift of a tape reel in a component supply part, or the like, are absorbed. As a result, it is possible to effectively suppress a physical stress from being imposed on an electronic component and the printed circuit board equipped therewith.

### SUMMARY

In the above-described adsorption nozzle, when both the nozzle member and the holder member are manufactured as designed, there is no wobble of the nozzle member against the holder member, and an attitude of the nozzle member projected from the holder member by an urging force of the urging member, i.e., an attitude of the adsorption nozzle can be always kept constant. It is unavoidable, however, to make a dimension error between the nozzle member and the holder member and it is difficult to suppress the above-described wobble to zero. For this reason, in some cases, the nozzle member is inclined with respect to the holder member by an angle in accordance with the above-described wobble and the attitude of the adsorption nozzle varies. Herein, the amount of tilt (angle) of the nozzle member can be measured in advance before the component transfer is performed. Therefore, if a tilt direction of the nozzle member is always a constant direction, as described later with reference to FIGS. 5A-5C, by considering the attitude of the adsorption nozzle at the time when the tip portion of the nozzle member is projected from the holder member, it is possible to perform the component transfer with high accuracy.

In the background-art apparatus, however, there has been no specific technology of controlling the attitude of the adsorption nozzle. For this reason, in the background-art apparatus, the tilt direction of the nozzle member is not constant, and this is one of main factors of accuracy degradation in the component transfer.

Accordingly, the present disclosure provides an adsorption nozzle and an attitude control method of the adsorption nozzle which make it possible to control an attitude of the adsorption nozzle at the time when a tip portion of a nozzle member is projected from a holder member, and a component transfer apparatus which transfers a component with high accuracy by using the adsorption nozzle.

A first aspect of the disclosure is an adsorption nozzle includes an axial nozzle member having a tip portion configured to adsorb a component; a holder member configured to slidably hold the nozzle member in a nozzle projection direction parallel to an axis line of the nozzle member; and an urging member configured to generate an urging force to slide the nozzle member in the nozzle projection direction and cause the tip portion of the nozzle member to be projected from the holder member. The adsorption nozzle also includes a locking part configured to locking the nozzle member projected from the holder member by the urging force, to thereby position the tip portion of the nozzle member at a projection limit position, wherein the locking part locks the nozzle member at a first locking position and a second locking position which are asymmetric with respect to the axis line, to thereby give a rotational moment to the nozzle member projected in the nozzle projection direction by the urging force, in a rotation direction which is uniquely determined by a relative relationship between the first locking position and the second locking position with respect to the axis line.

A second aspect of the disclosure is a component transfer apparatus. The apparatus includes the adsorption nozzle; and an adsorption head provided movably while configured to hold the holder member of the adsorption nozzle. A component positioned at a first position is adsorbed by the adsorption nozzle, and then is transferred to a second position different from the first position.

A third aspect of the disclosure is an attitude control method of an adsorption nozzle having an axial nozzle member having a tip portion configured to adsorb a component; a holder member configured to slidably hold the nozzle member in a nozzle projection direction parallel to an axis line of the nozzle member; an urging member configured to generate an urging force to slide the nozzle member in the nozzle projection direction and cause the tip portion of the nozzle member to be projected from the holder member; and a locking part configured to locking the nozzle member projected from the holder member by the urging force, to thereby position the tip portion of the nozzle member at a projection limit position. The method includes controlling an attitude of the nozzle member by giving a rotational movement to the nozzle member in a rotation direction when the nozzle member is projected from the holder member by the urging force in the nozzle projection direction, the rotational movement being given by locking the nozzle member at a first locking position and a second locking position which are asymmetric with respect to the axis line of the nozzle member, the rotation direction uniquely being determined by a relative relationship between the first locking position and the second locking position with respect to the axis line.

In the disclosure having such a configuration, the locking part locks the nozzle member projected from the holder member by the urging force at two positions, i.e., the first locking position and the second locking position. The tip portion of the nozzle member is thereby positioned at the projection limit position. At that time, since the first locking position and the second locking position are asymmetric with respect to the axis line of the nozzle member, the rotational moment is given to the nozzle member projected in the nozzle projection direction by the urging force, in the rotation direction which is uniquely determined by the relative relationship between the first locking position and the second locking position with respect to the axis line. As a result, in a case where there occurs a wobble of the nozzle member against the holder member, when the tip portion of the nozzle member is projected from the holder member, the adsorption nozzle takes an attitude in which the nozzle member is tilted in the above-described rotation direction.

Herein, the adsorption nozzle may have a configuration in which the nozzle member has a first engaging portion and a second engaging portion which are provided extending in parallel to the nozzle projection direction and the locking part supports the nozzle member slidably in the nozzle projection direction, in engagement with the first engaging portion and the second engaging portion, to thereby control rotation of the nozzle member around the axis line. In other words, the locking part having an attitude control function of the adsorption nozzle may be functioned as a rotation restricting member of the nozzle member. Thus, since the locking part has two kinds of functions, it is possible to provide a high-function adsorption nozzle while suppressing the number of components.

Further, as the first engaging portion, the second engaging portion, and the locking part, the following configuration may be used. For example, the first oblong hole and the second oblong hole which are provided extending in parallel to the nozzle projection direction in the sidewall of the nozzle member having the hollow structure inside which the suction path leading to the tip portion is provided may be used as the first engaging portion and the second engaging portion, respectively. Then, by disposing the first oblong hole, the second oblong hole, and the rotation restricting pin described above biasedly on one side of the orthogonal direction orthogonal to the axis line, it is possible to perform the attitude control of the adsorption nozzle and the rotation control of the nozzle member at the same time (see the first embodiment described later).

Furthermore, instead of adopting the above-described biased arrangement, by providing the first oblong hole, the second oblong hole, and the rotation restricting pin as described below, it is possible to perform the attitude control of the adsorption nozzle and the rotation control of the nozzle member at the same time. Specifically, there may be a configuration where the first oblong hole and the second oblong hole are opposed to each other across the axis line and when the tip portion of the nozzle member is projected from the holder member in the nozzle projection direction, in the anti-projection direction opposite to the nozzle projection direction, the first locking position formed with the first oblong hole and the first locking portion of the rotation restricting pin engaged with each other and the second locking position formed with the second oblong hole and the first locking portion of the rotation restricting pin engaged with each other are different from each other (see the second embodiment described later). Further, the adsorption nozzle may be attached so that the axis line of the rotation restricting pin is inclined with respect to the virtual line connecting the inner end surface position of the first oblong hole and the inner end surface position of the second oblong hole in the anti-projection direction (see the third embodiment described later). Furthermore, there may be a configuration where the inner end surface position of the first oblong hole and the inner end surface position of the second oblong hole are the same as each other in the anti-projection direction and the outer diameter of the first locking portion and the outer diameter of the second locking portion are different from each other (see the fourth embodiment described later).

Moreover, instead of adopting the above-described biased arrangement, by configuring the constituent elements of the adsorption nozzle as described below, it is possible to perform the attitude control of the adsorption nozzle and the rotation control of the nozzle member at the same time. Specifically, the two engaging portions are the first groove and the second groove, respectively, which are provided extending in the sidewall of the nozzle member in parallel to the axis line, the locking part has the first rotation restricting member attached to the holder member movably relative to the nozzle projection direction with respect to the nozzle member while being engaged with the first groove and the second rotation restricting member attached to the holder member movably relative to the nozzle projection direction with respect to the nozzle member while being engaged with the second groove, and the first groove and the second groove are opposed to each other across the axis line. When the tip portion of the nozzle member is projected from the holder member in the nozzle projection direction, in an anti-projection direction opposite to the nozzle projection direction, the first locking position formed with the first groove and the first rotation restricting member engaged with each other and the second locking position formed with the second groove and the second rotation restricting member engaged with each other are different from each other (see the fifth embodiment described later). Further, there may be a configuration where the first rotation restricting member and the second rotation restricting member are disposed at the same position in the nozzle projection direction and the inner end surface position of the first groove and the inner end surface position of the second groove are different from each other in the anti-projection direction (see the sixth embodiment described later). Furthermore, the first rotation restricting member and the second rotation restricting member may be disposed so as to intersect the virtual line connecting the first rotation restricting member and the second rotation restricting member. Further, there may be a configuration where the inner end surface position of the first groove and the inner end surface position of the second groove are the same as each other in the anti-projection direction and the outer diameter of the first rotation restricting member and the outer diameter of the second rotation restricting member are different from each other (see the seventh embodiment described later).

Thus, it is possible to control an attitude of an adsorption nozzle when a tip portion of a nozzle member is projected from a holder member. Further, by using such an adsorption nozzle whose attitude can be controlled, it is possible to perform component transfer with high accuracy.

### BRIEF DESCRIPTION OF THE DRAWINGS

FIG. 1 is a partial plan view schematically showing a component mounting apparatus equipped with a first embodiment of an adsorption nozzle in accordance with the present disclosure;

FIG. 2 is a view showing an appearance configuration of the adsorption nozzle;

FIG. 3 is a cross section of the adsorption nozzle shown in FIG. 2;

FIG. 4 is a perspective view showing a cross-sectional structure of the adsorption nozzle shown in FIG. 2;

FIGS. 5A-5C are views schematically showing a transfer operation of a component by a mounting head equipped with the adsorption nozzle shown in FIG. 2;

FIG. 6 is a perspective view showing a cross-sectional structure of an adsorption nozzle in accordance with a second embodiment of the present disclosure;

FIG. 7 is a perspective view showing a cross-sectional structure of an adsorption nozzle in accordance with a third embodiment of the present disclosure;

FIG. 8 is a perspective view showing a cross-sectional structure of an adsorption nozzle in accordance with a fourth embodiment of the present disclosure; and

FIG. 9 is a perspective view showing a cross-sectional structure of an adsorption nozzle in accordance with a fifth embodiment of the present disclosure.

### DETAILED DESCRIPTION

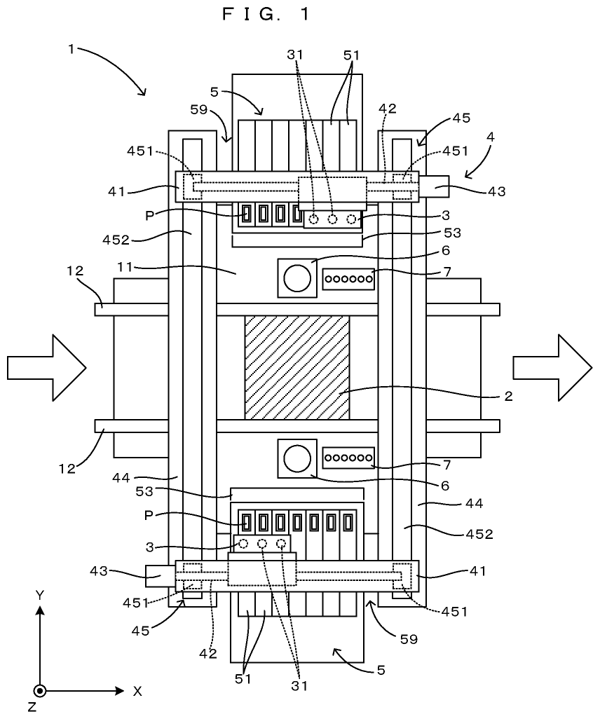

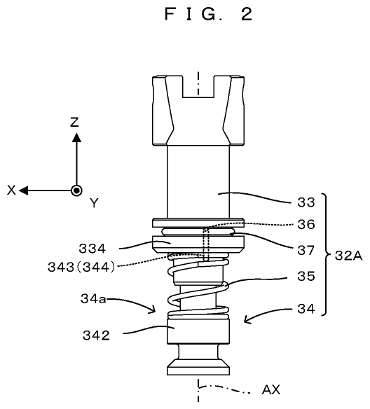

FIG. 1 is a partial plan view schematically showing a component mounting apparatus equipped with a first embodiment of an adsorption nozzle in accordance with the present disclosure. FIG. 2 is a view showing an appearance configuration of the adsorption nozzle. This component mounting apparatus 1 has a function of adsorbing a component by the adsorption nozzle at a component supply position and then transferring the component to a mounting position on a surface of a substrate, as a so-called component transfer apparatus. In this figure and the following figures, an XYZ rectangular coordinate system with a Z direction parallel to a vertical direction and an X direction and a Y direction each parallel to a horizontal direction is shown as appropriate.

This component mounting apparatus 1 includes a pair of conveyors 12 provided on a base 11. The component mounting apparatus 1 mounts components P by head units 3 onto a substrate 2 which is loaded from an upstream side in the X direction (substrate transfer direction) to an operation position (the position of the substrate 2 in FIG. 1) by the conveyors 12, and unloads the substrate 2 on which the component mounting is completed from the operation position to a downstream side in the X direction by using the conveyors 12.

The component mounting apparatus 1 includes an XY drive mechanism 4 for individually driving each of the two head units 3 in an XY direction. This XY drive mechanism 4 has a pair of X beams 41 and 41 which are each provided extending in parallel to the X direction and support the head units 3 movably in the X direction, respectively. To each of the X beams 41, attached are a ball screw 42 provided extending in parallel to the X direction and an X motor 43 for rotationally driving the ball screw 42. In this exemplary case, the X motor 43 is a servo motor. Then, the head unit 3 is attached to a nut of the ball screw 42. Further, the XY drive mechanism 4 has a pair of Y beams 44 and 44 which are each provided extending in parallel to the Y direction. One end of each X beam 41 is supported by one Y beam 44 movably in the Y direction, and the other end of each X beam 41 is supported by the other Y beam 44 movably in the Y direction. To each of the Y beams 44, attached is a Y motor 45 for driving the X beams 41 and 41 in the Y direction. In this exemplary case, each of the Y motors 45 is a linear motor and has movers 451 and 451 attached to the respective ends of the X beams 41 and 41 and a stator 452 provided extending in parallel to the Y direction. Then, by a magnetic force exerted between the mover 451 and the stator 452, the X beam 41 together with the mover 451 is driven in the Y direction. According to the XY drive mechanism 4, the head unit 3 can be moved in the XY direction by the X motor 43 and the Y motor 45.

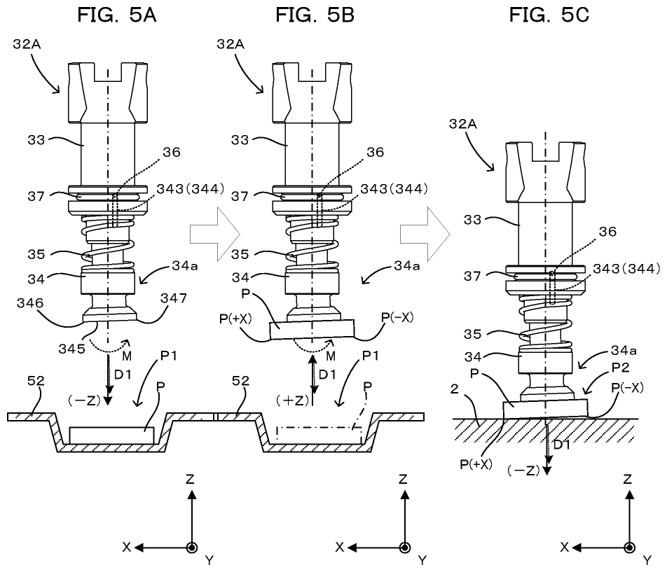

The component supply parts 5 are provided on both sides of the pair of conveyors 12 and 12, respectively, in the Y direction. In each of the component supply parts 5, a plurality of tape feeders 51 (hereinafter, referred to simply as “feeders 51”) are attached in a detachable/attachable manner, being aligned in the X direction. Each of the feeders 51 intermittently discharges a tape (represented by a reference sign 52 in FIGS. 5A-5C) in the Y direction, in which chip-like components P (chip components) such as an integrated circuit, a transistor, a capacitor, and the like are accommodated at predetermined pitches, to thereby supply the components P inside the tape to the component supply position.

The head unit 3 has a plurality of mounting heads 31 aligned in parallel to the X direction. Each of the mounting heads 31 has an elongated shape extending in the Z direction (vertical direction). At a lower end of the mounting head 31, provided is an adsorption nozzle 32A (FIG. 2) in accordance with the first embodiment of the present disclosure. The adsorption nozzle 32A has a holder nozzle 33 attached to the lower end portion of the mounting head 31 in a detachable/attachable manner and an axial shaft nozzle 34 attached to the holder nozzle 33 in an engageable/disengageable manner. In the adsorption nozzle 32A, the shaft nozzle 34 adaptable to the component P is selectively attached to the holder nozzle 33, and the component P can be thereby adsorbed/held. For this reason, the head unit 3 moves above the feeder 51 and uses the adsorption nozzle 32A to adsorb and hold the component P supplied by the feeder 51. Subsequently, the head unit 3 moves above the substrate 2 at the operation position and cancels the adsorption of the component P, to thereby mount the component P onto the substrate 2. Further, the detailed constitution and operation of the adsorption nozzle 32A will be described later in detail.

To the head unit 3, attached is a substrate recognition camera (not shown) for capturing an image of a fiducial mark given to the substrate 2 from vertically thereabove. Therefore, positional deviation of the substrate 2 can be recognized from the image of the substrate 2 which is captured by the substrate recognition camera. Further, in the present embodiment, the substrate recognition camera can capture an image of a nozzle storage part 7 from vertically thereabove, as well as the substrate 2. Then, stocker-side arrangement information on the arrangement of nozzles and/or nozzle accommodation parts can be acquired on the basis of the image of the nozzle storage part 7 captured by the substrate recognition camera.

Further, a component recognition camera 6 and the nozzle storage part 7 are disposed between the component supply part 5 and the conveyor 12. The component recognition camera 6 captures an image of the component P adsorbed by the adsorption nozzle 32A in the component supply part 5 and provides image information to be used to acquire component information and positional deviation information. This component image capture is performed when the head unit 3 passes above the component recognition camera 6 during movement from the component supply part 5 to the substrate 2. By analyzing the image acquired thus, the amount of positional deviation and the rotation angle of the adsorbed component P in a XY plane can be obtained. Further, in the present embodiment, the component recognition camera 6 can capture an image of a lower surface of the head unit 3 from vertically therebelow, as well as the component P.

The nozzle storage part 7 has a nozzle stocker for storing a plurality of adsorption nozzles 32A. Then, when an instruction to attach the adsorption nozzle 32A corresponding to the component P is given, the head unit 3 moves above the nozzle stocker and then the mounting head 31 moves up in the vertical direction Z, to access the nozzle stocker. The adsorption nozzle 32A is thereby changed.

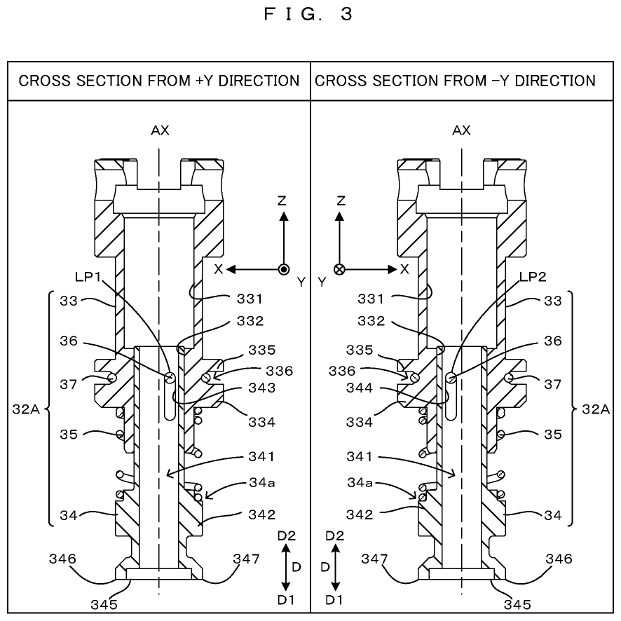

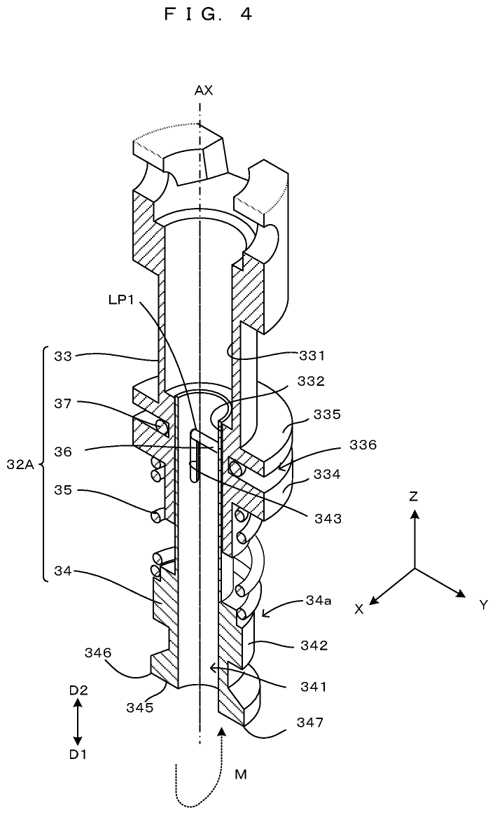

FIG. 3 is a cross section of the adsorption nozzle shown in FIG. 2, and the left column in this figure shows a cross section as viewed from a (+Y) direction and the right column in this figure shows a cross section as viewed from a (−Y) direction. Further, FIG. 4 is a perspective view showing a cross-sectional structure of the adsorption nozzle shown in FIG. 2. Furthermore, FIGS. 5A-5C are views schematically showing a transfer operation of the component by the mounting head equipped with the adsorption nozzle shown in FIG. 2. FIGS. 5A and 5B each show a pickup operation of the component at the component supply position, and FIG. 5C shows a mounting operation of the component onto the substrate.

The mounting head 31 has a head body (now shown) which is liftably driven and rotationally driven with respect to the head unit 3. Inside the head body, formed is a negative pressure passage for supplying a negative pressure or the like for component adsorption to the adsorption nozzle 32A having the following configuration.

The adsorption nozzle 32A has the holder nozzle 33 which is a portion attached to the head body in a detachable/attachable manner, the shaft nozzle 34, a compression coil spring 35, a rotation restricting pin 36, and an O-ring 37. The holder nozzle 33 has a cylindrical structure in which an attachment hole 331 for receiving a lower end portion of the head body and a holding hole 332 for holding the shaft nozzle 34 are continuous with each other in the vertical direction Z.

The shaft nozzle 34 has a shaft structure, in more detail, a substantially cylindrical hollow structure including a suction path 341 penetrating therethrough in the vertical direction Z. This shaft nozzle 34 is inserted into the holding hole 332 of the holder nozzle 33, being slidable with respect to the holder nozzle 33 in a direction D parallel to the axis line AX of the shaft nozzle 34.

Further, in order to add a buffing function to the adsorption nozzle 32A, provided is the compression coil spring 35 as an example of an “urging member” of the present disclosure. Specifically, the holder nozzle 33 has flange portions 334 and 335 in two upper and lower stages on the outer periphery thereof. Further, the shaft nozzle 34 has a flange portion 342 on the outer periphery thereof. Then, the compression coil spring 35 is extrapolated into the holder nozzle 33 and the shaft nozzle 34 so as to be interposed between the flange portions 334 and 342 opposed to each other in the vertical direction Z. For this reason, the shaft nozzle 34 is urged by an elastic force of the compression coil spring 35 in a direction (toward the lower side in this figure) going away from the holder nozzle 33. As shown in FIGS. 2 to 5C, except when the mounting head 31 receives the component P from the feeder 51 or mounts the component P onto the substrate 2, the shaft nozzle 34 is projected from the holder nozzle 33 in a nozzle projection direction D1. On the other hand, in the component receival or the component mounting, as the mounting head 31 moves down in the vertical direction, i.e., a (−Z) direction, with a tip portion (lower end) of the shaft nozzle 34 in contact with an upper surface of the component P, the shaft nozzle 34 is retracted with respect to the holder nozzle 33 against the elastic force of the compression coil spring 35 in an anti-projection direction D2 opposite to the nozzle projection direction D1. Thus, the shaft nozzle 34 makes elastic displacement with respect to the holder nozzle 33, and a collision load of the shaft nozzle 34 on the component P is absorbed by the compression coil spring 35.

As described above, the adsorption nozzle 32A is provided with a rotation control structure in which rotation with respect to the holder nozzle 33 (rotation about the axis line AX) is controlled by the rotation restricting pin 36 while slide of the shaft nozzle 34 with respect to the holder nozzle 33 is allowed. More specifically, a first oblong hole 343 and a second oblong hole 344 are provided in parallel to the nozzle projection direction D1 in a sidewall of the shaft nozzle 34 which is finished into a substantially cylindrical shape. These oblong holes 343 and 344 are provided biasedly on a (−X) direction side in an orthogonal direction X orthogonal to the axis line AX of the shaft nozzle 34. Moreover, respective end portions of these oblong holes 343 and 344 on the side of anti-projection direction D2 reach a height position which is the same as that of an annular groove portion 336 formed between the flange portions 334 and 335, as shown in FIGS. 3 to 5C.

In this groove portion 336, through holes (not shown) are provided at positions corresponding to the oblong holes 343 and 344. Then, a round bar-like rotation restricting pin 36 is inserted into one through hole, penetrating the first oblong hole 343, the suction path 341, and the second oblong hole 344, and reaches the other through hole. Thus, the rotation restricting pin 36 is attached to the holder nozzle 33, being disposed biasedly in the (−X) direction with respect to the axis line AX of the shaft nozzle 34. For this reason, the slide of the shaft nozzle 34 relative to the holder nozzle 33 is performed, with the rotation restricting pin 36 engaged with respective inner wall surfaces of the oblong holes 343 and 344. In other words, the tip portion 34a of the shaft nozzle 34 is projected from the holder nozzle 33 by an elastic force, being subjected to the rotation control by the rotation restricting pin 36. Moreover, the projection is stopped when respective inner end surfaces of the oblong holes 343 and 344 on the side of anti-projection direction D2 are locked by the rotation restricting pin 36. Specifically, the rotation restricting pin 36 positions the tip portion 34a of the shaft nozzle 34 at a limit position (i.e., a projection limit position) at which the tip portion 34a is projected from the holder nozzle 33, and corresponds to an example of a “locking part” of the present disclosure.

Further, as the through hole is provided in the above-described groove portion 336, the O-ring 37 is attached to the groove portion 336. It is thereby possible to suppress inflow of air toward the suction path 341 and prevent degradation in the adsorption performance of the adsorption nozzle 32A.

Next, with reference to FIGS. 5A-5C, a component adsorption operation, a component transfer operation, and a component mounting operation by the adsorption nozzle 32A having the above-described configuration will be described. As shown in FIG. 5A, a tape 52 accommodating the component P is supplied to the component supply position P1 by the feeder 51. In order to pick up the component P, the mounting head 31 is moved so that the adsorption nozzle 32A should be positioned above the component supply position P1. At that time, the tip portion 34a of the shaft nozzle 34 is projected from the holder nozzle 33 by the elastic force. Herein, in a case where the holder nozzle 33 and the shaft nozzle 34 have respective sizes as designed, there occurs no wobble of the shaft nozzle 34 against the holder nozzle 33, and the nozzle projection direction D1 is downward in the vertical direction, i.e., in parallel to the (−Z) direction. On the other hand, when the above-described wobble occurs, the nozzle projection direction D1 is inclined with respect to the vertical direction Z, and an attitude of the adsorption nozzle 32A varies. In the background-art apparatus, as described earlier, no structure to control the attitude of the adsorption nozzle 32A is not included, and the tilt direction is random.

In contrast to this, in the first embodiment, the rotation control structure to control the rotation (rotation about the axis) of the shaft nozzle 34 with respect to the holder nozzle 33 is constructed as above. Specifically, the rotation restricting pin 36 supports the shaft nozzle 34 slidably in the nozzle projection direction D1, being engaged with the oblong holes 343 and 344 on the (−X) direction side with respect to the axis line AX, to thereby control the rotation of the shaft nozzle 34 about the axis line AX. Moreover, in a state where the tip portion 34a of the shaft nozzle 34 is positioned at the projection limit position, the rotation restricting pin 36 locks the respective inner end surfaces of the oblong holes 343 and 344 on the side of anti-projection direction D2, and a locking position (first locking position LP1) of the oblong hole 343 and a locking position (second locking position LP2) of the oblong hole 344 are each disposed biasedly on the (−X) direction side with respect to the axis line AX. As a result, as shown in FIG. 5A, the nozzle projection direction D1 is inclined counterclockwise in this paper, and a rotational moment M represented by a dotted line in this figure is added to the shaft nozzle 34 which receives the elastic force in the nozzle projection direction D1, an end portion 346 of a tip surface 345 of the shaft nozzle 34 on the (+X) direction side is positioned lower than an end portion 347 on the (−X) direction side. Therefore, in order to pick up the component P, as represented by a solid arrow in FIG. 5A, when the mounting head 31 moves down in the (−Z) direction, the end portion 346 of the shaft nozzle 34 first comes into contact with the component P. Then, when the mounting head 31 further moves down, the whole of the tip surface 345 of the shaft nozzle 34 comes into contact with the upper surface of the component P, to thereby firmly adsorb the component P.

When the component adsorption operation is completed, the mounting head 31 moves up in the (+Z) direction, and with this moving-up, the tip portion 34a of the shaft nozzle 34 is projected relatively from the holder nozzle 33 in the nozzle projection direction D1. Then, when the component P adsorbed by the adsorption nozzle 32A moves up away from the tape 52, as shown in FIG. 5B, the nozzle projection direction D1 is inclined counterclockwise in this paper like before the component adsorption operation. For this reason, the adsorbed component P is inclined in the same way and transferred to above the substrate 2 in this state (component transfer operation).

After the component P is positioned above a component mounting position P2 on a surface of the substrate 2, where the component P is to be mounted, the above-described component transfer operation is stopped and the component mounting operation is started. At that time, an attitude of the component P always corresponds to the attitude of the adsorption nozzle 32A in the component adsorption operation. As shown in FIGS. 5B and 5C, for example, at the point in time when the adsorption nozzle 32A is moved in a horizontal direction and transferred to above the component mounting position P2 after the component adsorption, the nozzle projection direction D1 is inclined counterclockwise in this paper, and the end portion P (+X) on the (+X) direction side below the component P is positioned lower than the end portion (−X) on the (−X) direction side. Further, though the mounting head 31 is sometimes rotated as necessary before the component mounting is performed, the component P adsorbed and held by the adsorption nozzle 32A after the rotation is inclined in a direction corresponding to the attitude in the component adsorption operation. Subsequently, when the mounting head 31 is moved down so as to mount the component P onto the substrate 2, as shown in FIG. 5C, for example, the end portion P (+X) of the component P is first placed at the component mounting position P2. Then, when the mounting head 31 further moves down, the whole of the component P adsorbed by the adsorption nozzle 32A is placed on the surface of the substrate 2. Subsequently, the adsorption and holding by the adsorption nozzle 32A is canceled, and the mounting of the component P is thereby completed.

As described above, in the first embodiment, the tip portion 34a of the shaft nozzle 34 is projected by the elastic force of the compression coil spring 35 relatively from the holder nozzle 33 in the nozzle projection direction D1. Moreover, the first locking position LP1 and the second locking position LP2 are provided asymmetrically with respect to the axis line AX. Therefore, the tilt direction of the nozzle projection direction D1 with respect to the (−Z) direction is uniquely determined by a relative relationship between the first locking position LP1 and the second locking position LP2 with respect to the axis line AX. In other words, the adsorption nozzle 32A at the time when the tip portion 34a of the shaft nozzle 34 is projected from the holder nozzle 33 always takes an attitude in which the shaft nozzle 34 is inclined in the above-described rotation direction. Therefore, by obtaining the amount of deviation in the mounting corresponding to the tilt of the component attitude in the component adsorption due to the wobble in advance, without having an effect due to the individual difference of the adsorption nozzle 32A, it is possible to transfer the component P from the component supply position P1 to the component mounting position P2 with high accuracy.

Further, in the first embodiment, the oblong holes 343 and 344 extending in parallel to the nozzle projection direction D1 are provided in the sidewall of the shaft nozzle 34. Then, the rotation restricting pin 36 supports the shaft nozzle 34 slidably in the nozzle projection direction D1, being engaged with these oblong holes 343 and 344, to thereby control the rotation of the shaft nozzle 34 about the axis line AX. Thus, the rotation restricting pin 36 has both an attitude control function of the adsorption nozzle 32A and a rotation control function of the shaft nozzle 34. As a result, it is possible to obtain a high-function adsorption nozzle 32A with the smaller number of components.

As described above, in the first embodiment, the shaft nozzle 34 and the holder nozzle 33 correspond to respective examples of a “nozzle member” and a “holder member” of the present disclosure. Further, the oblong hole 343 corresponds to an example of a “first engaging portion” and an example of a “first oblong hole” of the present disclosure, and the oblong hole 344 corresponds to an example of a “second engaging portion” and an example of a “second oblong hole” of the present disclosure. Furthermore, the elastic force of the compression coil spring 35 corresponds to an example of an “urging force” of the present disclosure. Further, the mounting head 31 corresponds to an example of an “adsorption head” of the present disclosure.

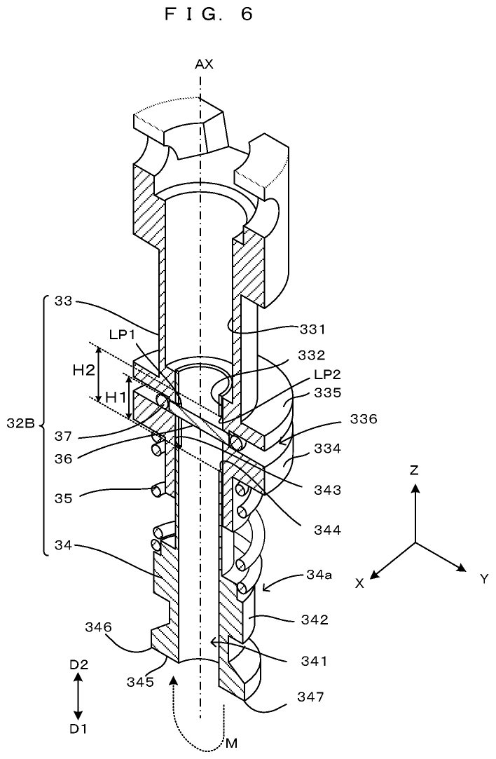

FIG. 6 is a perspective view showing a cross-sectional structure of an adsorption nozzle in accordance with the second embodiment of the present disclosure. The second embodiment is largely different from the first embodiment in the configuration of the oblong holes 343 and 344 and the rotation restricting pin 36, and the other constituent elements are basically the same as those in the first embodiment. Hereinafter, description will be made, centering on the difference, and the constituent elements identical to those in the first embodiment are represented by the same reference signs and description thereof will be omitted.

In an adsorption nozzle 32B in accordance with the second embodiment, as shown in FIG. 6, the oblong holes 343 and 344 are opposed to each other across the axis line AX in the Y direction. The respective lengths H1 and H2 of these oblong holes 343 and 344 in the direction D satisfy an inequality (H1<H2). Then, the oblong holes 343 and 344 are provided in the sidewall of the shaft nozzle 34 so that a position (hereinafter, referred to as a “first inner end surface position”) of the inner end surface of the oblong hole 343 in the anti-projection direction D2 should be lower than a position (hereinafter, referred to as a “second inner end surface position”) of the inner end surface of the oblong hole 344 in the anti-projection direction D2.

Further, two through holes are formed in the groove portion 336. These through holes are opposed to each other across the axis line AX in the Y direction. Then, the round bar-like rotation restricting pin 36 is inserted into one through hole, penetrating the first oblong hole 343, the suction path 341, and the second oblong hole 344, and reaches the other through hole. Therefore, respective outer diameters of both end portions of the rotation restricting pin 36 are the same as each other, and since the first inner end surface position is lower than the second inner end surface position in the anti-projection direction D2, respective locking positions of the shaft nozzle 34 by the rotation restricting pin 36 are different from each other in the Y direction. In more detail, when the tip portion 34a of the shaft nozzle 34 is projected relatively from the holder nozzle 33 by the elastic force of the compression coil spring 35 in the nozzle projection direction D1, as shown in this figure, the locking portion on the (−Y) direction side of the rotation restricting pin 36 is engaged with the first inner end surface position, to thereby form the first locking position LP1. The moving of the shaft nozzle 34 on the (−Y) direction side is controlled at this first locking position LP1. With a short delay from this, the locking portion on the (+Y) direction side of the rotation restricting pin 36 is engaged with the second inner end surface position, to thereby form the second locking position LP2. The moving of the shaft nozzle 34 on the (+Y) direction side is controlled at this second locking position LP2. The tip portion 34a of the shaft nozzle 34 is thereby positioned at the projection limit position.

As described above, in the second embodiment, the first locking position LP1 and the second locking position LP2 are asymmetric with respect to the axis line AX. In more detail, in the direction D, the second locking position LP2 is positioned in the anti-projection direction D2 by a predetermined distance (=H2−H1), as compared with the first locking position LP1. For this reason, like in the first embodiment, when there occurs a wobble of the shaft nozzle 34 against the holder nozzle 33, the rotational moment M is added in the rotation direction which is uniquely determined by the relative relationship between the first locking position LP1 and the second locking position LP2 with respect to the axis line AX. Therefore, the adsorption nozzle 32B at the time when the tip portion 34a of the shaft nozzle 34 is projected from the holder nozzle 33 always takes an attitude in which the shaft nozzle 34 is inclined in the above-described rotation direction. As a result, functions and effects similar to those of the first embodiment are obtained.

Further, in the second embodiment, the locking portion on the (−Y) direction side of the rotation restricting pin 36 corresponds to an example of a “first locking portion” of the present disclosure, and the locking portion on the (+Y) direction side corresponds to an example of a “second locking portion” of the present disclosure.

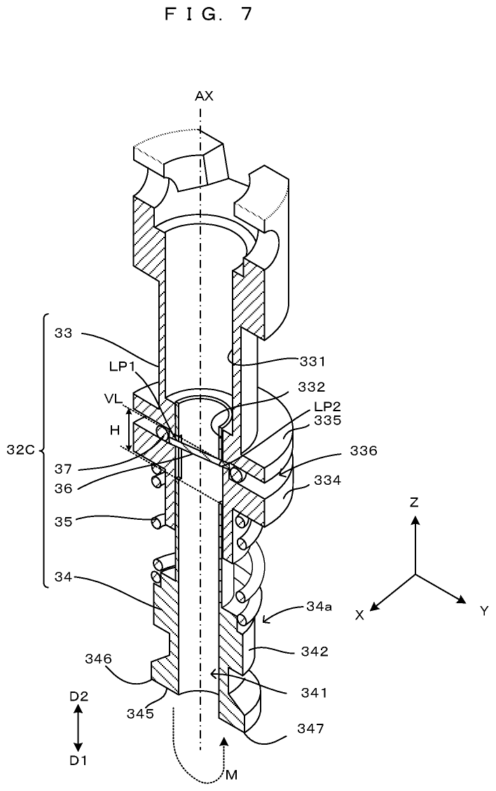

FIG. 7 is a perspective view showing a cross-sectional structure of an adsorption nozzle in accordance with the third embodiment of the present disclosure. The third embodiment is largely different from the second embodiment in the configuration of the oblong holes 343 and 344 and the rotation restricting pin 36, and the other constituent elements are basically the same as those in the second embodiment. Hereinafter, description will be made, centering on the difference, and the constituent elements identical to those in the second embodiment are represented by the same reference signs and description thereof will be omitted.

In an adsorption nozzle 32C in accordance with the third embodiment, as shown in FIG. 7, the oblong holes 343 and 344 are opposed to each other across the axis line AX in the Y direction. The respective lengths H of these oblong holes 343 and 344 in the direction D are the same as each other, and moreover, the oblong holes 343 and 344 are provided at the same height in the direction D. Therefore, the first inner end surface position and the second inner end surface position are also positioned at the same height in the direction D.

Further, the third embodiment is the same as the second embodiment in that two through holes are formed in the groove portion 336 and the round bar-like rotation restricting pin 36 is inserted into the through hole, but is different from the second embodiment in the following point. Specifically, in the direction Z, the through hole on the (−Y) direction side is disposed at a position lower than that of the through hole on the (+Y) direction side. For this reason, the round bar-like rotation restricting pin 36 is inserted into one through hole, penetrating the first oblong hole 343, the suction path 341, and the second oblong hole 344, and reaches the other through hole. For this reason, the rotation restricting pin 36 is attached to the holder nozzle 33 so that the axis line should be inclined to a virtual line VL (line parallel to the Y direction in the third embodiment) connecting the first inner end surface position and the second inner end surface position. Therefore, though respective outer diameters of both the end portions of the rotation restricting pin 36 are the same as each other, the locking portion on the (−Y) direction side of the rotation restricting pin 36 is positioned lower than the locking portion on the (+Y) direction side in the direction Z. In the third embodiment, when the tip portion 34a of the shaft nozzle 34 is projected relatively from the holder nozzle 33 by the elastic force of the compression coil spring 35 in the nozzle projection direction D1, as shown in this figure, the locking portion on the (+Y) direction side of the rotation restricting pin 36 is engaged with the second inner end surface position, to thereby form the second locking position LP2. The moving of the shaft nozzle 34 on the (+Y) direction side is controlled at this second locking position LP2. With a short delay from this, the locking portion on the (−Y) direction side of the rotation restricting pin 36 is engaged with the first inner end surface position, to thereby form the first locking position LP1. The moving of the shaft nozzle 34 on the (−Y) direction side is controlled at this first locking position LP1. The tip portion 34a of the shaft nozzle 34 is thereby positioned at the projection limit position.

As described above, also in the third embodiment, the first locking position LP1 and the second locking position LP2 are asymmetric with respect to the axis line AX. In more detail, in the direction D, the second locking position LP2 is positioned in the anti-projection direction D2 by the amount of tilt of the rotation restricting pin 36 from the virtual line VL, as compared with the first locking position LP1. For this reason, like in the second embodiment, when there occurs a wobble of the shaft nozzle 34 against the holder nozzle 33, the rotational moment M is added in the rotation direction which is uniquely determined by the relative relationship between the first locking position LP1 and the second locking position LP2 with respect to the axis line AX. Therefore, the adsorption nozzle 32C at the time when the tip portion 34a of the shaft nozzle 34 is projected from the holder nozzle 33 always takes an attitude in which the shaft nozzle 34 is inclined in the above-described rotation direction. As a result, functions and effects similar to those of the first and second embodiments are obtained.

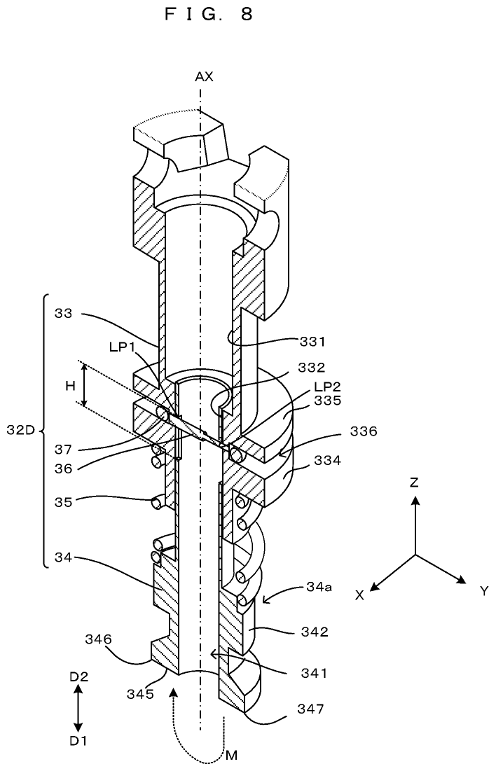

FIG. 8 is a perspective view showing a cross-sectional structure of an adsorption nozzle in accordance with the fourth embodiment of the present disclosure. The fourth embodiment is largely different from the second embodiment in the configuration of the oblong holes 343 and 344 and the rotation restricting pin 36, and the other constituent elements are basically the same as those in the second embodiment. Hereinafter, description will be made, centering on the difference, and the constituent elements identical to those in the second embodiment are represented by the same reference signs and description thereof will be omitted.

In an adsorption nozzle 32D in accordance with the fourth embodiment, as shown in FIG. 8, the oblong holes 343 and 344 are opposed to each other across the axis line AX in the Y direction. The respective lengths H of these oblong holes 343 and 344 in the direction D are the same as each other, and moreover, the oblong holes 343 and 344 are provided at the same height in the direction D. Therefore, the first inner end surface position and the second inner end surface position are also positioned at the same height in the direction D.

Further, the fourth embodiment is the same as the second embodiment in that two through holes are formed in the groove portion 336 and the rotation restricting pin 36 is inserted into the through hole, but is different from the second embodiment in the following point. Specifically, in the direction Z, an inner diameter of the through hole on the (−Y) direction side is larger than that of the through hole on the (+Y) direction side, and the stepped round bar-like rotation restricting pins 36 having outer diameters corresponding thereto are inserted. In other words, a locking portion having a small outer diameter on the (+Y) direction side of the rotation restricting pin 36 is inserted into the through hole having a large inner diameter on the (−Y) direction side, penetrating the first oblong hole 343, the suction path 341, and the second oblong hole 344, and reaches the through hole having a small inner diameter on the (+Y) direction side. Thus, when the rotation restricting pin 36 is inserted, as shown in this figure, a locking portion having a large outer diameter on the (−Y) direction side of the rotation restricting pin 36 is positioned in the first oblong hole 343 and the locking portion having a small outer diameter on the (+Y) direction side of the rotation restricting pin 36 is positioned in the second oblong hole 344.

In the fourth embodiment, when the tip portion 34a of the shaft nozzle 34 is projected relatively from the holder nozzle 33 by the elastic force of the compression coil spring 35 in the nozzle projection direction D1, as shown in this figure, the locking portion on the (−Y) direction side of the rotation restricting pin 36 is engaged with the first inner end surface position, to thereby form the first locking position LP1. The moving of the shaft nozzle 34 on the (−Y) direction side is controlled at this first locking position LP1. With a short delay from this, the locking portion on the (+Y) direction side of the rotation restricting pin 36 is engaged with the second inner end surface position, to thereby form the second locking position LP2. The moving of the shaft nozzle 34 on the (+Y) direction side is controlled at this second locking position LP2. The tip portion 34a of the shaft nozzle 34 is thereby positioned at the projection limit position.

As described above, also in the fourth embodiment, the first locking position LP1 and the second locking position LP2 are asymmetric with respect to the axis line AX. In more detail, in the direction D, the second locking position LP2 is positioned in the anti-projection direction D2 by half of an outer diameter difference between a locking portion having a small outer diameter and a locking portion having a large outer diameter, as compared with the first locking position LP1. For this reason, like in the second embodiment, when there occurs a wobble of the shaft nozzle 34 against the holder nozzle 33, the rotational moment M is added in the rotation direction which is uniquely determined by the relative relationship between the first locking position LP1 and the second locking position LP2 with respect to the axis line AX. Therefore, the adsorption nozzle 32D at the time when the tip portion 34a of the shaft nozzle 34 is projected from the holder nozzle 33 always takes an attitude in which the shaft nozzle 34 is inclined in the above-described rotation direction. As a result, functions and effects similar to those of the first and second embodiments are obtained.

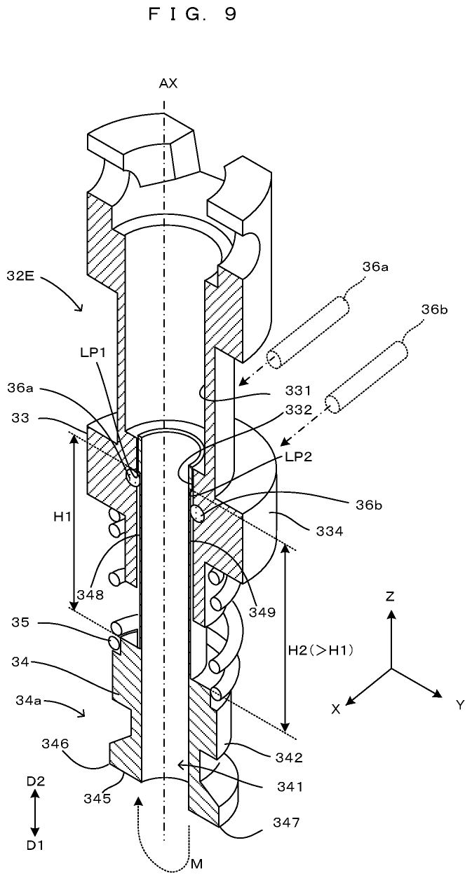

Further, the present disclosure is not limited to the above-described embodiments and numerous modifications and variations can be added to those described above without departing from the scope of the disclosure. In the above-described first to fourth embodiments, for example, in order to control the rotation of the shaft nozzle 34, the present disclosure is applied to the adsorption nozzles 32A to 32D formed of a combination of the two oblong holes 343 and 344 and one rotation restricting pin 36. The configuration for rotation control is not limited to this, but as disclosed in JP2008-300598A1, for example, there is a configuration formed of a combination of an engagement groove and a pin, and a technical matter included in the above-described second to fourth embodiments can be applied to the adsorption nozzle having the configuration. Hereinafter, by the combination of the engagement groove and the pin, it is possible to control the rotation of the shaft nozzle 34 and control the attitude of the adsorption nozzle. The fifth embodiment will be described, with reference to FIG. 9.

FIG. 9 is a perspective view showing a cross-sectional structure of an adsorption nozzle in accordance with the fifth embodiment of the present disclosure. The fifth embodiment is largely different from the second embodiment in that instead of the oblong holes 343 and 344, a first groove 348 and a second groove 349 are each provided on an outer surface of the shaft nozzle 34, in that two through holes 334a and 334b are provided in the flange portion 334 in the X direction, and in that round bar-like rotation restricting pins 36a and 36b extending in the X direction are inserted into the through holes 334a and 334b, respectively, and the other constituent elements are basically the same as those in the second embodiment. Hereinafter, description will be made, centering on the difference, and the constituent elements identical to those in the second embodiment are represented by the same reference signs and description thereof will be omitted.

In an adsorption nozzle 32E in accordance with the fifth embodiment, as shown in FIG. 9, the first groove 348 and the second groove 349 are opposed to each other across the axis line AX in the Y direction, having respective lengths H1 and H2 (>H1) in the direction D, and provided extending in the nozzle projection direction D1. Further, the first groove 348 and the second groove 349 are provided in the sidewall of the shaft nozzle 34 so that a position (hereinafter, referred to as a “third inner end surface position”) of the inner end surface of the groove 348 in the anti-projection direction D2 should be lower than a position (hereinafter, referred to as a “fourth inner end surface position”) of the inner end surface of the groove 349 in the anti-projection direction D2.

As shown in FIG. 9, the first groove 348 partially intersects the through hole 334a. For this reason, when the rotation restricting pin 36a is inserted into the first groove 348 and attached to the holder nozzle 33, part of a side surface of the rotation restricting pin 36a is inserted into the first groove 348. On the other hand, the second groove 349 partially intersects the through hole 334b. For this reason, when the rotation restricting pin 36b is inserted into the second groove 349 and attached to the holder nozzle 33, part of a side surface of the rotation restricting pin 36b is inserted into the second groove 349. For this reason, when the tip portion 34a of the shaft nozzle 34 is projected relatively from the holder nozzle 33 by the elastic force of the compression coil spring 35 in the nozzle projection direction D1, as shown in this figure, the side surface of the rotation restricting pin 36a is engaged with the third inner end surface position, to thereby form the first locking position LP1. The moving of the shaft nozzle 34 on the (−Y) direction side is controlled at this first locking position LP1. With a short delay from this, the side surface of the rotation restricting pin 36b is engaged with the fourth inner end surface position, to thereby form the second locking position LP2. The moving of the shaft nozzle 34 on the (+Y) direction side is controlled at this second locking position LP2. The tip portion 34a of the shaft nozzle 34 is thereby positioned at the projection limit position.

As described above, also in the fifth embodiment, the first locking position LP1 and the second locking position LP2 are asymmetric with respect to the axis line AX. In more detail, in the direction D, the second locking position LP2 is positioned in the anti-projection direction D2 by a predetermined distance (=H2−H1), as compared with the first locking position LP1. For this reason, like in the second embodiment, when there occurs a wobble of the shaft nozzle 34 against the holder nozzle 33, the rotational moment M is added in the rotation direction which is uniquely determined by the relative relationship between the first locking position LP1 and the second locking position LP2 with respect to the axis line AX. Therefore, the adsorption nozzle 32B at the time when the tip portion 34a of the shaft nozzle 34 is projected from the holder nozzle 33 always takes an attitude in which the shaft nozzle 34 is inclined in the above-described rotation direction. As a result, the same action effect as that in the second embodiment can be produced.

Thus, in the fifth embodiment, the rotation restricting pins 36a and 36b correspond to respective examples of a “first rotation restricting member” and a “second rotation restricting member” of the present disclosure and each serve as a “locking part” of the present disclosure.

Instead of the configuration where the third inner end surface position is lower than the fourth inner end surface position in the direction D, the same configuration as that of the third or fourth embodiment may be adopted. Specifically, there may be a configuration where the grooves 348 and 349 are provided so that the third inner end surface position and the fourth inner end surface position should have the same height in the direction D and the through hole 334a is provided at a position lower than that of the through hole 334b in the vertical direction Z. In such a configuration, in the direction D, the second locking position LP2 is positioned in the anti-projection direction D2 by a height difference between the third inner end surface position and the fourth inner end surface position, as compared with the first locking position LP1, and functions and effects similar to those of the third embodiment are obtained (the sixth embodiment).

Further, there may be a configuration where the grooves 348 and 349 are provided so that the third inner end surface position and the fourth inner end surface position should have the same height in the direction D and the outer diameter of the rotation restricting pin 36a is made larger than the outer diameter of the rotation restricting pin 36b. In such a configuration, in the direction D, the second locking position LP2 is positioned in the anti-projection direction D2 by an outer diameter difference between the rotation restricting pins 36a and 36b, as compared with the first locking position LP1, and functions and effects similar to those of the fourth embodiment are obtained (the seventh embodiment).

Furthermore, in the fifth to seventh embodiments, though the rotation restricting pins 36a and 36b are used as the “first rotation restricting member” and “second rotation restricting member”, respectively, of the present disclosure, the shape of each of the first rotation restricting member and the second rotation restricting member is not limited to the round-bar shape, but may be any other shape, such as a spherical shape.

Further, in the above-described embodiments, though the present disclosure is applied to the component mounting apparatus 1 serving as the component transfer apparatus, an application target of the present disclosure is not limited to this but the present disclosure can be applied to any other component transfer apparatus (for example, an IC handler, a component testing machine, or the like).

What is claimed is:

1. An adsorption nozzle, comprising:
an axial nozzle member having a tip portion configured to adsorb a component;
a holder member configured to slidably hold the nozzle member in a nozzle projection direction parallel to an axis line of the nozzle member;
an urging member configured to generate an urging force to slide the nozzle member in the nozzle projection direction and cause the tip portion of the nozzle member to be projected from the holder member; and
a locking part configured to lock the nozzle member projected from the holder member by the urging force, to position the tip portion of the nozzle member at a projection limit position,
wherein the locking part is configured to lock the nozzle member at a first locking position and a second locking position which are asymmetric with respect to the axis line, to give a rotational moment to the nozzle member projected in the nozzle projection direction by the urging force, in a rotation direction which is uniquely determined by a relative relationship between the first locking position and the second locking position with respect to the axis line.

2. The adsorption nozzle according to claim 1, wherein
the nozzle member has a first engagement portion and a second engagement portion which extend in parallel to the nozzle projection direction, and
the locking part is configured to support the nozzle member slidably in the nozzle projection direction while engaging with the first engagement portion and the second engagement portion, so as to restrict rotation of the nozzle member around the axis line.

3. The adsorption nozzle according to claim 2, wherein
the nozzle member has a hollow structure inside which configures a suction path leading to the tip portion,
the first engagement portion and the second engagement portion are a first oblong hole and a second oblong hole, respectively, which extend in parallel to the nozzle projection direction in a sidewall of the nozzle member,
the locking part is a rotation restricting pin penetrating the first oblong hole, the suction path, and the second oblong hole, to attach to the holder member, and
the first oblong hole, the second oblong hole, and the rotation restricting pin are disposed biasedly on one side of an orthogonal direction orthogonal to the axis line.

4. The adsorption nozzle according to claim 2, wherein
the nozzle member has a hollow structure inside which configures a suction path leading to the tip portion,
the first engagement portion and the second engagement portion are a first oblong hole and a second oblong hole, respectively, which extend in parallel to the nozzle projection direction in a sidewall of the nozzle member,
the locking part is a rotation restricting pin penetrating the first oblong hole, the suction path, and the second oblong hole, to attach to the holder member,
the first oblong hole and the second oblong hole are opposed to each other across the axis line, and
when the tip portion of the nozzle member is projected from the holder member in the nozzle projection direction, the first locking position and the second locking portion are different from each other in an anti-projection direction opposite to the nozzle projection direction, the first locking position being a position where the first oblong hole and the first locking portion of the rotation restricting pin are engaged with each other, the second locking position being a position where the second oblong hole and the second locking portion of the rotation restricting pin are engaged with each other.

5. The adsorption nozzle according to claim 4, wherein
the rotation restricting pin extends in an orthogonal direction orthogonal to the axis line and finished so that an outer diameter of the first locking portion and an outer diameter of the second locking portion are the same as each other, and
an inner end surface position of the first oblong hole and an inner end surface position of the second oblong hole are different from each other in the anti-projection direction.

6. The adsorption nozzle according to claim 4, wherein
an axis line of the rotation restricting pin is inclined with respect to a virtual line connecting an inner end surface position of the first oblong hole and an inner end surface position of the second oblong hole in the anti-projection direction.

7. The adsorption nozzle according to claim 4, wherein
an inner end surface position of the first oblong hole and an inner end surface position of the second oblong hole are the same as each other in the anti-projection direction, and
an outer diameter of the first locking portion and an outer diameter of the second locking portion are different from each other.

8. The adsorption nozzle according to claim 2, wherein
the first engagement portion and the second engagement portion are a first groove and a second groove, respectively, which extend in a sidewall of the nozzle member in parallel to the axis line,
the locking part has a first rotation restricting member attached to the holder member movably relative to the nozzle projection direction with respect to the nozzle member while being engaged with the first groove and a second rotation restricting member attached to the holder member movably relative to the nozzle projection direction with respect to the nozzle member while being engaged with the second groove,
the first groove and the second groove are opposed to each other across the axis line, and
when the tip portion of the nozzle member is projected from the holder member in the nozzle projection direction, the first locking position and the second locking portion are different from each other in an anti-projection direction opposite to the nozzle projection direction, the first locking position being a position where the first groove and the first rotation restricting member are engaged with each other, the second locking position being a position where the second groove and the second rotation restricting member are engaged with each other.

9. The adsorption nozzle according to claim 8, wherein
the first rotation restricting member and the second rotation restricting member are disposed at the same position in the nozzle projection direction, and
an inner end surface position of the first groove and an inner end surface position of the second groove are different from each other in the anti-projection direction.

10. The adsorption nozzle according to claim 8, wherein
the first rotation restricting member and the second rotation restricting member are disposed so as to intersect a virtual line connecting the first rotation restricting member and the second rotation restricting member.

11. The adsorption nozzle according to claim 8, wherein
an inner end surface position of the first groove and an inner end surface position of the second groove are the same as each other in the anti-projection direction, and
an outer diameter of the first rotation restricting member and an outer diameter of the second rotation restricting member are different from each other.

12. A component transfer apparatus, comprising:
the adsorption nozzle according to claim 1; and
an adsorption head is configured to move while configured to hold the holder member of the adsorption nozzle,
wherein a component positioned at a first position is adsorbed by the adsorption nozzle, and then is transferred to a second position different from the first position.

13. An attitude control method of an adsorption nozzle having an axial nozzle member having a tip portion configured to adsorb a component; a holder member configured to slidably hold the nozzle member in a nozzle projection direction parallel to an axis line of the nozzle member; an urging member configured to generate an urging force to slide the nozzle member in the nozzle projection direction and cause the tip portion of the nozzle member to be projected from the holder member; and a locking part configured to locking the nozzle member projected from the holder member by the urging force, to position the tip portion of the nozzle member at a projection limit position, the method comprising:
controlling an attitude of the nozzle member by giving a rotational movement to the nozzle member in a rotation direction when the nozzle member is projected from the holder member by the urging force in the nozzle projection direction, the rotational movement being given by locking the nozzle member at a first locking position and a second locking position which are asymmetric with respect to the axis line of the nozzle member, the rotation direction uniquely being determined by a relative relationship between the first locking position and the second locking position with respect to the axis line.

14. An adsorption nozzle, comprising:
an axial nozzle member having a tip portion configured to adsorb a component;
a holder member configured to slidably hold the nozzle member in a nozzle projection direction parallel to an axis line of the nozzle member;
an urging member interposed between the nozzle member and the holder member and configured to generate an urging force in the nozzle projection direction for causing the nozzle member to slide in the nozzle projection direction and projecting the tip portion of the nozzle member from the holder member; and
a locking part configured to locking the nozzle member projected from the holder member by the urging force, to position the tip portion of the nozzle member at a projection limit position,
wherein the nozzle member has a hollow structure inside which configures a suction path leading to the tip portion, and
the locking part includes a rotation restricting pin inserted along a direction orthogonal to the axis line and passing into the suction path to attach to the holder member and locks the nozzle member at a first locking position and a second locking position which are asymmetric with respect to the axis line by the rotation restricting pin, to give a rotational moment to the nozzle member projected in the nozzle projection direction by the urging force, in a rotation direction which is uniquely determined by a relative relationship between the first locking position and the second locking position with respect to the axis line.

15. An attitude control method of an adsorption nozzle having an axial nozzle member having a tip portion configured to adsorb a component; a holder member configured to slidably hold the nozzle member in a nozzle projection direction parallel to an axis line of the nozzle member; an urging member interposed between the nozzle member and the holder member and configured to generate an urging force in the nozzle projection direction for causing the nozzle member to slide in the nozzle projection direction and projecting the tip portion of the nozzle member from the holder member; and a locking part configured to locking the nozzle member projected from the holder member by the urging force, to position the tip portion of the nozzle member at a projection limit position, the method comprising:
controlling an attitude of the nozzle member by giving a rotational movement to the nozzle member in a rotation direction when the nozzle member is projected from the holder member by the urging force in the nozzle projection direction, the rotational movement being given by locking the nozzle member at a first locking position and a second locking position which are asymmetric with respect to the axis line of the nozzle member with a rotation restricting pin of the locking part, the rotation direction uniquely being determined by a relative relationship between the first locking position and the second locking position with respect to the axis line,
wherein the nozzle member has a hollow structure inside which configures a suction path leading to the tip portion, and
the rotation restricting pin is inserted along a direction orthogonal to the axis line and passes into the suction path to attach to the holder member.

16. A component transfer apparatus, comprising:
the adsorption nozzle according to claim 2; and
an adsorption head is configured to move while configured to hold the holder member of the adsorption nozzle,
wherein a component positioned at a first position is adsorbed by the adsorption nozzle, and then is transferred to a second position different from the first position.

17. A component transfer apparatus, comprising:
the adsorption nozzle according to claim 3; and
an adsorption head is configured to move while configured to hold the holder member of the adsorption nozzle,
wherein a component positioned at a first position is adsorbed by the adsorption nozzle, and then is transferred to a second position different from the first position.

18. A component transfer apparatus, comprising:
the adsorption nozzle according to claim 3; and
an adsorption head is configured to move while configured to hold the holder member of the adsorption nozzle,
wherein a component positioned at a first position is adsorbed by the adsorption nozzle, and then is transferred to a second position different from the first position.

19. A component transfer apparatus, comprising:
the adsorption nozzle according to claim 4; and
an adsorption head is configured to move while configured to hold the holder member of the adsorption nozzle,
wherein a component positioned at a first position is adsorbed by the adsorption nozzle, and then is transferred to a second position different from the first position.

20. A component transfer apparatus, comprising:
the adsorption nozzle according to claim 5; and
an adsorption head is configured to move while configured to hold the holder member of the adsorption nozzle,
wherein a component positioned at a first position is adsorbed by the adsorption nozzle, and then is transferred to a second position different from the first position.
